(19) United States
(12) Patent Application Publication
(10) Pub. No.: US 2005/0287719 A1
(43) Pub. Date: Dec. 29, 2005

(54) Organic thin film transistor array panel and manufacturing method thereof

(76) Inventors: Min-Seong Ryu, Suwon-si (KR); Tae-Young Choi, Seoul (KR); Yong-Uk Lee, Seongnam-si (KR); Woo-Jae Lee, Yongin-si (KR); Bo-Sung Kim, Seoul (KR)

Correspondence Address: CANTOR COLBURN, LLP, 55 GRIFFIN ROAD SOUTH, BLOOMFIELD, CT, 06002, US

(21) Appl. No.: 11/143,158

(22) Filed: Jun. 2, 2005

(30) Foreign Application Priority Data
Jun. 14, 2004 (KR) 2004-0043462

(51) Int. Cl. H01L 21/00; H01L 21/84

(52) U.S. Cl. 438/149

(57) ABSTRACT

A method of manufacturing a thin film transistor array panel includes: forming a gate line on a substrate; forming a gate insulating layer on the gate line; forming a data line and a drain electrode on the gate insulating layer; depositing an organic semiconductor layer on the data line, the drain electrode and exposed portions of the gate insulating layer; depositing a protection layer on the organic semiconductor layer; forming a photoresist on the protection layer, the photoresist having positive photosensitivity; etching the protection layer and the organic semiconductor layer using the photoresist as an etch mask; forming a passivation layer on the protection layer, the data line, and the drain electrode, the passivation layer having a contact hole exposing a portion of the drain electrode; and forming a pixel electrode on the passivation layer, the pixel electrode electrically connected to the drain electrode via the contact hole.

This application claims priority to Korean Patent Application No. 10-2004-0043462, filed on Jun. 14, 2004, the contents of which in its entirety are herein incorporated by reference.

### BACKGROUND OF THE INVENTION

(a) Field of the Invention

The present invention relates to a thin film transistor array panel and a manufacturing method thereof, and in particular, to an organic thin film transistor array panel and a manufacturing method thereof.

(b) Description of Related Art

Electric field effect transistors including organic semiconductors have been vigorously researched as driving devices for next generation display devices. Organic semiconductors may be classified as either low molecule compounds such as oligothiophene, pentacene, phthalocyanine, and C₆O; or high molecule compounds such as polythiophene and polythienylenevinylene. The low molecule compounds have a high mobility in a range of about 0.05-1.5 msV, and superior on/off current ratios.

However, conventional manufacturing processes for organic thin film transistors (TFTs) including low molecule compounds are complicated since they require a low molecule semiconductor pattern to be formed by using a shadow mask and vacuum deposition in order to avoid solvent-induced in-plane expansion.

As an alternative to conventional lithography using organic solvents, aqueous-based photolithography is suggested by Jackson in U.S. Pat. No. 6,696,370. However, Jackson requires use of a negative photosensitive film and still suggests a complicated process.

### SUMMARY OF THE INVENTION

A method of manufacturing a thin film transistor array panel is provided, the method includes: forming a gate line on a substrate; forming a gate insulating layer on the gate line; forming a data line and a drain electrode on the gate insulating layer; depositing an organic semiconductor layer on the data line, the drain electrode and exposed portions of the gate insulating layer; depositing a protection layer on the organic semiconductor layer; forming a photoresist on the protection layer, the photoresist having a positive photosensitivity; etching the protection layer and the organic semiconductor layer using the photoresist as an etch mask; forming a passivation layer on the protection layer, the data line, and the drain electrode, the passivation layer having a contact hole exposing a portion of the drain electrode; and forming a pixel electrode on the passivation layer, the pixel electrode electrically connected to the drain electrode via the contact hole.

The protection layer may include aqueous-based organic material and may include polyvinyl alcohol (PVA). The protection layer may be insensitive to light. The organic semiconductor layer may be soluble in an organic solvent.

The organic semiconductor layer may include at least one of: tetracene, pentacene, and derivatives thereof with substituent; oligothiophene including four to eight thiophenes connected at the positions 2, 5 of thiophene rings; perylenetetracarboxylic dianhydride (PTCDA), naphthalenetetracarboxylic dianhydride (NTCDA), and imide derivatives thereof; metallized phthalocyanine and halogenated derivatives thereof; cooligomer and co-polymer of thienylene and vinylene; regioregular polythiophene; perylene, coroene, and derivatives thereof with substituent; and aromatic and heteroaromatic ring of the above-described materials with at least one hydrocarbon chain having one to thirty carbon atoms.

The gate insulating layer may include at least one of silicon dioxide, silicon nitride, maleimide-styrene, polyvinylphenol (PVP), and modified cyanoethylpullulan (m-CEP). The gate insulating layer may be surface treated with octadecyl-trichloro-silane.

A thin film transistor array panel is provided, which includes: a gate line formed on a substrate; a gate insulating layer formed on the gate line; a data line and a drain electrode formed on the gate insulating layer; an organic semiconductor formed on a portion of the drain electrode; a protection member formed on the organic semiconductor and having substantially the same planar shape as the organic semiconductor; a passivation layer formed on the protection layer, a portion of the data line, and a portion of the drain electrode, the passivation layer having a contact hole exposing a portion of the drain electrode; and a pixel electrode formed on the passivation layer, the pixel electrode electrically connected to the drain electrode via the contact hole.

The protective member may include aqueous-based organic material and the protective member may be insensitive to light. The protective member may include PVA. The organic semiconductor may be soluble in an organic solvent.

The organic semiconductor may include at least one of: tetracene, pentacene, and derivatives thereof with substituent; oligothiophene including four to eight thiophenes connected at the positions 2, 5 of thiophene rings; perylenetetracarboxylic dianhydride (PTCDA), naphthalenetetracarboxylic dianhydride (NTCDA), and imide derivatives thereof; metallized phthalocyanine and halogenated derivatives thereof; co-oligomer and co-polymer of thienylene and vinylene; regioregular polythiophene; perylene, coroene, and derivatives thereof with substituent; and aromatic and heteroaromatic ring of the above-described materials with at least one hydrocarbon chain having one to thirty carbon atoms.

The gate insulating layer may include at least one of silicon dioxide, silicon nitride, maleimide-styrene, polyvinylphenol (PVP), and modified cyanoethylpullulan (m-CEP). The gate insulating layer may have a surface treated by octadecyl-trichloro-silane.

The gate line may include a gate electrode extended from the gate line and substantially fully covered by the organic semiconductor.

### BRIEF DESCRIPTION OF THE DRAWINGS

The present invention will become more apparent by describing exemplary embodiments thereof in detail with reference to the accompanying drawing in which:

FIG. 1 is a layout view of an exemplary TFT array panel for an LCD device according to an exemplary embodiment of the present invention;

FIG. 2 is a sectional view of the TFT array panel shown in FIG. 1 taken along line II-II′;

FIGS. 3, 5, 8 and 10 are layout views of a TFT array panel shown in FIGS. 1 and 2 in intermediate steps of a manufacturing method thereof according to an exemplary embodiment of the present invention;

FIG. 4 is a sectional view of the TFT array panel shown in FIG. 3 taken along line IV-IV′;

FIG. 6 is a sectional view of the TFT array panel shown in FIG. 5 taken along line VI-VI′;

FIG. 7 is a sectional view of the TFT array panel shown in FIG. 5 taken along line VI-VI′, which illustrates a manufacturing step following a manufacturing step shown in FIG. 6;

FIG. 9 is a sectional view of the TFT array panel shown in FIG. 8 taken along line IX-IX′; and

FIG. 11 is a sectional view of the TFT array panel shown in FIG. 10 taken along line XI-XI′.

### DETAILED DESCRIPTION OF THE INVENTION

The present invention will be described more fully hereinafter with reference to the accompanying drawings, in which exemplary embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

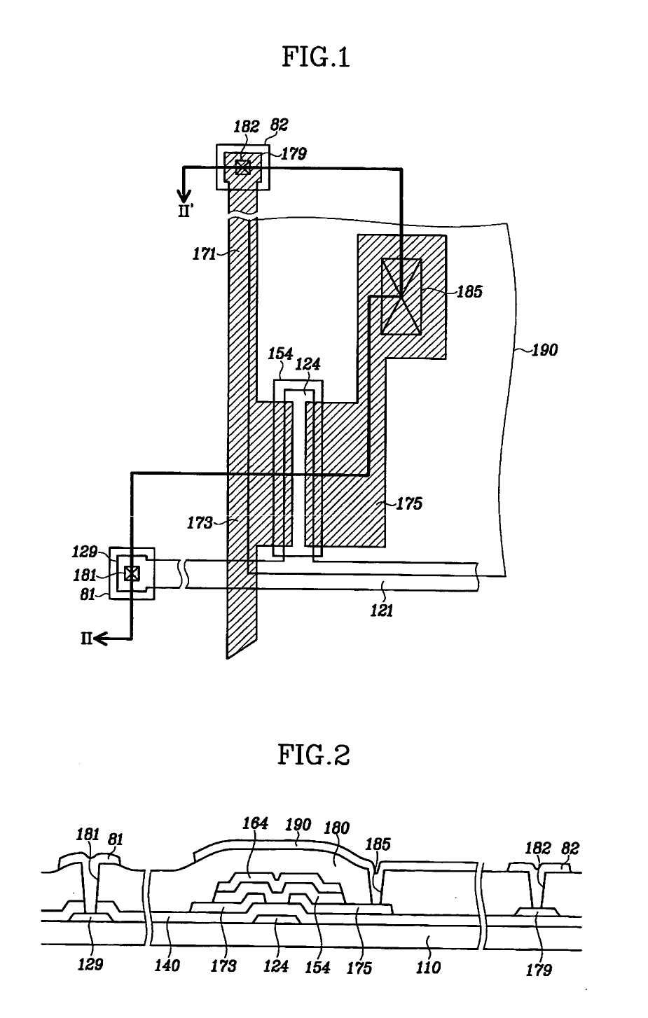

A thin film transistor (TFT) array panel according to an exemplary embodiment of the present invention will be described with reference to FIGS. 1 and 2.

FIG. 1 is a layout view of an exemplary TFT array panel for an LCD device according to an exemplary embodiment of the present invention, and FIG. 2 is a sectional view of the TFT array panel shown in FIG. 1 taken along line II-II′.

Gate lines 121 are formed on an insulating substrate 110 such as transparent glass. The gate lines 121 extend substantially in a transverse direction of the TFT array panel to transmit gate signals. Each gate line 121 includes gate electrodes 124 protruding upward and an end portion 129 having a large area for contact with another layer or a driving circuit. The gate lines 121 may extend to be connected to a driving circuit (not shown) that may be integrated on the insulating substrate 110.

The gate lines 121 are, for example, made of Al containing metal such as Al and Al alloy, Ag containing metal such as Ag and Ag alloy, Cu containing metal such as Cu and Cu alloy, Au containing material such as Au and Au alloy, Mo containing metal such as Mo and Mo alloy, Cr, Ti or Ta. The gate lines 121 may have a multi-layered structure including two films having different physical characteristics. A first film is, for example, made of low resistivity metal including Al containing metal, Ag containing metal, and Cu containing metal for reducing signal delay or voltage drop in the gate lines 121. A second film is, for example, made of material such as Mo containing metal, Cr, Ta or Ti, which has good physical, chemical, and electrical contact characteristics with other materials such as indium tin oxide (ITO) or indium zinc oxide (IZO). Examples of a combination of the first and second films include a lower Cr film with an upper Al (alloy) film and a lower Al (alloy) film with an upper Mo (alloy) film. However, the first and second films may be made of various metals or conductors.

Lateral sides of the gate lines 121 are inclined relative to a surface of the insulating substrate 110. An inclination angle of the lateral sides of the gate lines 121 ranges from about 30 degrees to about 80 degrees.

A gate insulating layer 140 is formed on the gate lines 121. The gate insulating layer 140 is, for example, made of silicon dioxide (SiO₂) and has a surface treated with octadecyl-trichoro-silane (OTS). However, the gate insulating layer 140 may be made of silicon nitride (SiNx) or organic material such as maleimide-styrene, polyvinylphenol (PVP), and modified cyanoethylpullulan (m-CEP).

Data lines 171 and drain electrodes 175 are formed on the gate insulating layer 140. The data lines 171 extend substantially in the longitudinal direction of the TFT array panel to transmit data voltages and traverse the gate lines 121. Each data line 171 includes an end portion 179 having a large area for contact with another layer or an external device and source electrodes 173 projecting toward the gate electrodes 124. Each pair of the source electrodes 173 and the drain electrodes 175 are spaced apart from each other and disposed opposite each other with respect to each gate electrode 124.

Like the gate lines 121, the data lines 171 and the drain electrodes 175 have inclined edge profiles, and inclination angles thereof range from about 30 degrees to about 80 degrees.

Organic semiconductor islands 154 are formed on the source electrodes 173, the drain electrodes 175, and the gate insulating layer 140. The organic semiconductor islands 154 fully cover the gate electrodes 124 such that the edges of the gate electrodes 124 overlap the organic semiconductor islands 154.

The organic semiconductor islands 154 may include a high molecular compound or a low molecular compound that is soluble in an aqueous solution or organic solvent. Usually, a high molecular organic semiconductor is very soluble in solvent and thus suitable for printing. Some types of low molecular organic semiconductors are very soluble in organic solvent, which are suitable for the semiconductor islands 154.

In an exemplary embodiment, the organic semiconductor islands 154 may be made of tetracene, or pentacene with substituent, or derivatives thereof. Alternatively, the organic semiconductor islands 154 may be made of oligothiophene including four to eight thiophenes connected at positions 2, 5 of thiophene rings.

In another exemplary embodiment, the organic semiconductor islands 154 may be made of perylenetetracarboxylic dianhydride (PTCDA), naphthalenetetracarboxylic dianhydride (NTCDA), or imide derivatives thereof.

Alternatively, the organic semiconductor islands 154 may be made of metallized phthalocyanine or halogenated derivatives thereof. The metallized phthalocyanine may include Cu, Co, Zn, etc.

As another alternative, the organic semiconductor islands 154 may be made of co-oligomer or co-polymer of thienylene and vinylene. In addition, organic semiconductor islands 154 may be made of regioregular polythiophene.

In another exemplary embodiment, the organic semiconductor islands 154 may be made of perylene, coronene or derivatives thereof with substituent.

In still another exemplary embodiment, the organic semiconductor islands 154 may be made of derivatives of aromatic or heteroaromatic ring of the above-described derivatives with at least one hydrocarbon chain having one to thirty carbon atoms.

A gate electrode 124, a source electrode 173, and a drain electrode 175 along with a semiconductor island 154 form a TFT having a channel formed in the semiconductor island 154 disposed between the source electrode 173 and the drain electrode 175.

Protective members 164 are formed on the semiconductor islands 154 such that a protective member 164 is formed on each one of the semiconductor islands 154. The protective members 164 are, for example, made of an aqueous-based organic material such as polyvinyl alcohol (PVA), which is water-soluble and insensitive to light. The protective members 164 have substantially a same planar shape as the semiconductor islands 154 upon which the protective members 164 are formed.

A passivation layer 180 is formed on the data lines 171, the drain electrodes 175, and the protective members 164. The passivation layer 180 is, for example, made of an inorganic insulator such as silicon nitride or silicon oxide, an organic insulator, or a low dielectric insulating material. The low dielectric insulating material includes, for example, a dielectric constant lower than 4.0. Examples of the low dielectric insulating material include a-Si:C:O and a-Si:O:F formed by plasma enhanced chemical vapor deposition (PECVD). The organic insulator may have photosensitivity and the passivation layer 180 may have a flat surface. The passivation layer 180 may have a double-layered structure including a lower inorganic film and an upper organic film so that the passivation layer may take advantage of the organic film as well as protect exposed portions of the organic semiconductor island 154.

The passivation layer 180 includes contact holes 182 and 185 exposing end portions 179 of the data lines 171 and the drain electrodes 175, respectively. The passivation layer 180 and the gate insulating layer 140 have a contact holes 181 exposing end portions 129 of the gate lines 121.

Pixel electrodes 190 are formed on the passivation layer 180, and contact assistants 81 and 82 are formed in the contact holes 181 and 182, respectively. The pixel electrodes 190 and the contact assistants 81 and 82 are, for example, made of transparent conductor such as ITO or IZO or reflective conductor such as Ag or Al.

The pixel electrodes 190 are physically and electrically connected to the drain electrodes 175 through the contact holes 185 such that the pixel electrodes 190 receive the data voltages from the drain electrodes 175. When supplied with the data voltages, the pixel electrodes 190 generate electric fields in cooperation with a common electrode (not shown) disposed opposite the pixel electrodes 190 and supplied with a common voltage. The electric fields generated between the pixel electrodes 190 and the common electrode determine orientations of liquid crystal molecules in a liquid crystal layer (not shown) disposed between the pixel electrodes 190 and the common electrode or yield currents in a light emitting layer (not shown) to emit light. The pixel electrodes 190 overlap the gate lines 121 and the data lines 171 to increase aperture ratio.

The contact assistants 81 and 82 are connected to the end portions 129 of the gate lines 121 and the end portions 179 of the data lines 171 through the contact holes 181 and 182, respectively. The contact assistants 81 and 82 protect the end portions 129 and 179, respectively, and complement the adhesiveness of the end portions 129 and 179 and external devices.

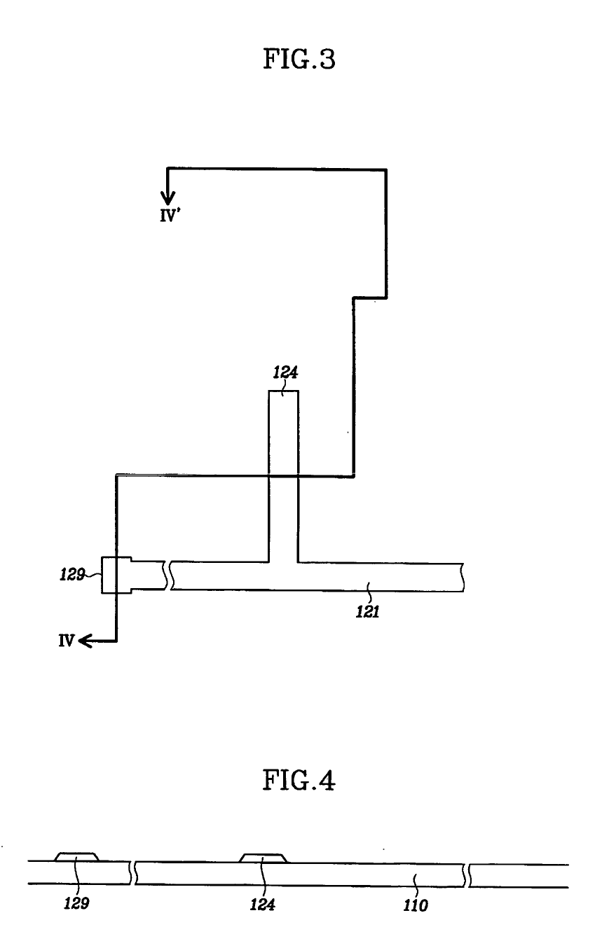

Turning now to FIGS. 3 through 11, a method of manufacturing the TFT array panel shown in FIGS. 1-2 according to an exemplary embodiment of the present invention will be described.

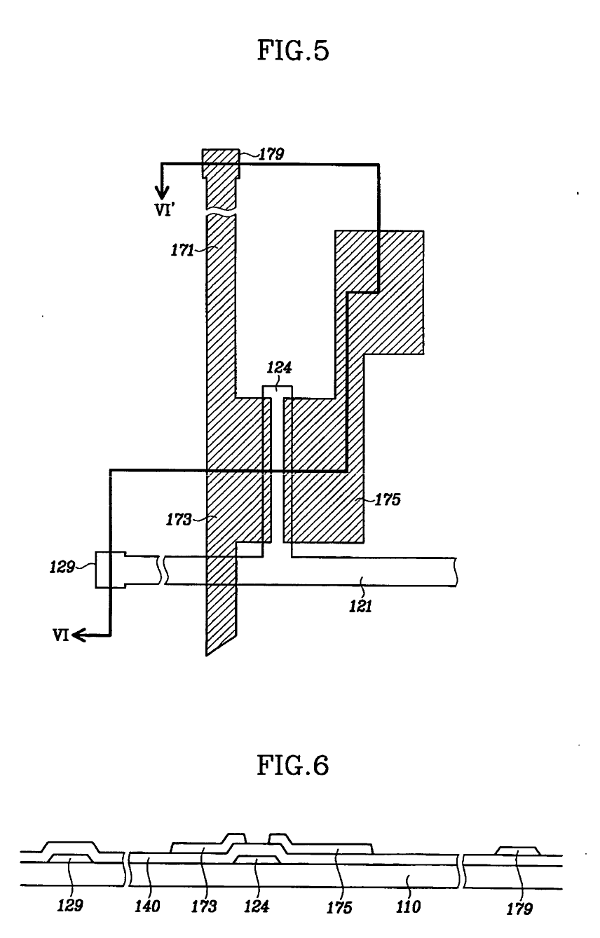

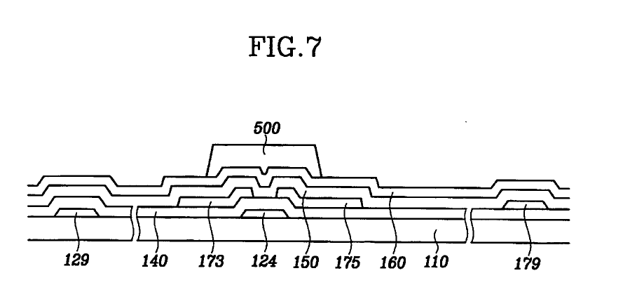

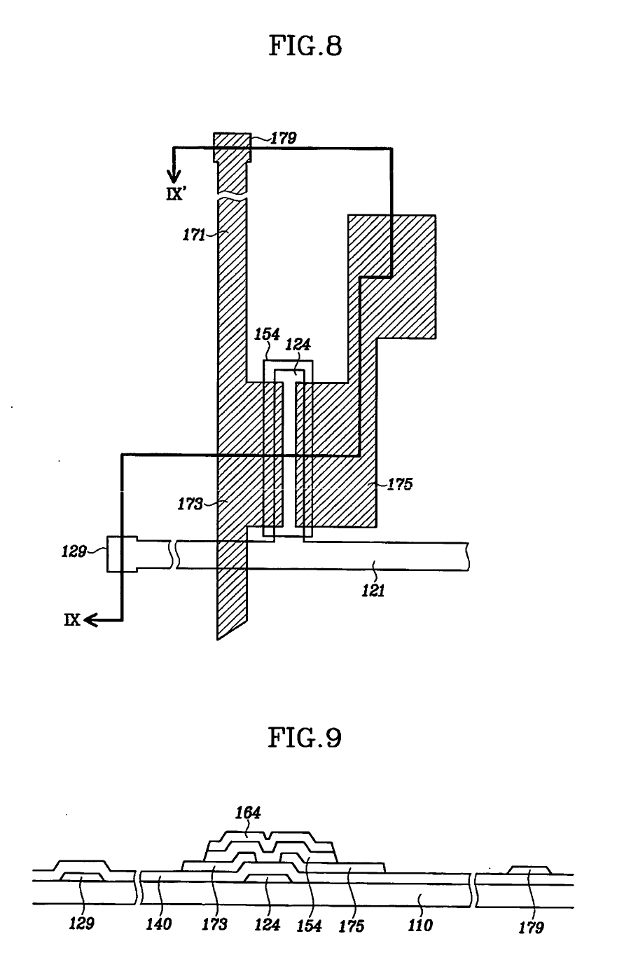

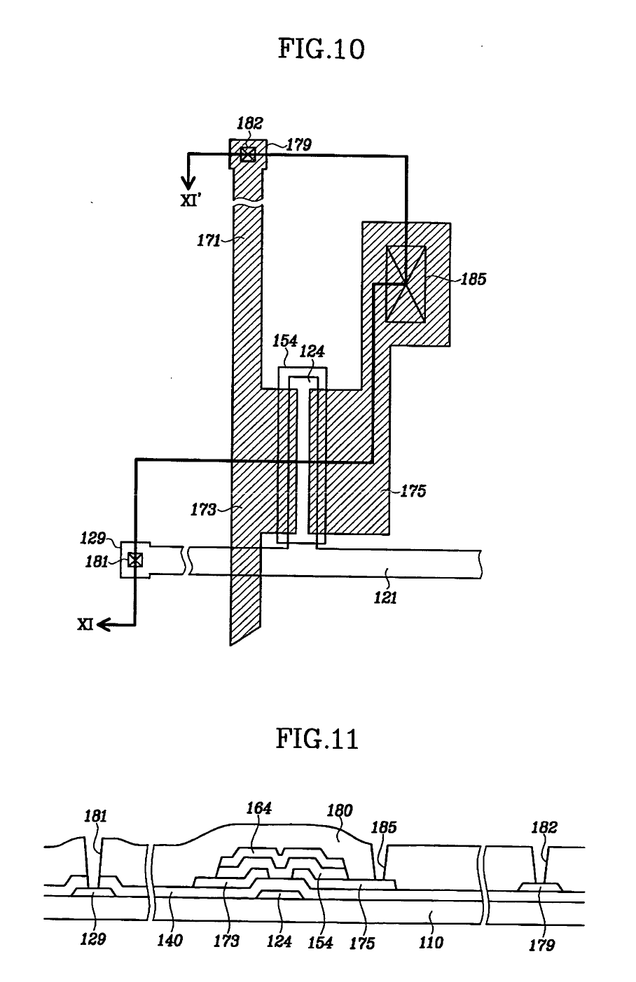

FIGS. 3, 5, 8 and 10 are layout views of a TFT array panel shown in FIGS. 1 and 2 in intermediate steps of a method of manufacturing the TFT array panel according to an exemplary embodiment of the present invention. FIG. 4 is a sectional view of the TFT array panel shown in FIG. 3 taken along line IV-IV′. FIG. 6 is a sectional view of the TFT array panel shown in FIG. 5 taken along line VI-VI′. FIG. 7 is a sectional view of the TFT array panel shown in FIG. 5 taken along line VI-VI′, which illustrates a manufacturing step following a manufacturing step shown in FIG. 6. FIG. 9 is a sectional view of the TFT array panel shown in FIG. 8 taken along line IX-IX′. FIG. 11 is a sectional view of the TFT array panel shown in FIG. 10 taken along line XI-XI′.

Referring to FIGS. 3 and 4, a gate line 121 including a gate electrode 124 and an end portion 129 are formed on an insulating substrate 110 that is made of, for example, transparent glass, silicone or plastic.

Referring to FIGS. 5 and 6, a gate insulating layer 140 is deposited on an insulating substrate 110, for example, by chemical vapor deposition (CVD). The gate insulating layer 140 may have a thickness that is equal to, or about 500-3,000 Å and the gate insulating layer 140 may be dipped, for example, in OTS. Thereafter, a conductive layer that is made of, for example, low resistivity metal such as Au is deposited on the gate insulating layer 140 by vacuum heat deposition, etc, and the conductive layer is patterned by, for example, lithography and etching to form data lines 171 including source electrodes 173 and end portions 179 and drain electrodes 175.

Referring to FIG. 7, an organic semiconductor layer 150 is formed over the source electrodes 173, the drain electrodes 175, the end portion 179 and exposed portions of the gate insulating layer 140. The organic semiconductor layer 150 is deposited by, for example, molecular beam deposition, vapor deposition, vacuum sublimation, CVD, PECVD, reactive deposition, sputtering, spin coating, etc.

An insulating layer 160 (protection layer), which is made of, for example, aqueous-based photo-insensitive organic material is deposited on the organic semiconductor layer 150. The insulating layer 160 may be prepared by applying an aqueous solution including photo-insensitive organic material onto the organic semiconductor layer 150. The application of the organic material may be performed by, for example, spin coating, dip coating, spray coating, or solvent coating. Since the insulating layer 160 is water-soluble, the insulating layer 160 does not affect characteristics of the organic semiconductor layer 150.

Next, a photoresist 500 is formed at a portion of the insulating layer 160 corresponding to the gate electrodes 124. The photoresist 500 may be formed by coating a positive photoresist film on the insulating layer 160 and subjecting the photoresist 500 to light exposure and development. Since the insulating layer 160 is insensitive to light, the light exposure to the photoresist film does not affect characteristics of the insulating layer 160.

Referring to FIGS. 8 and 9, the insulating layer 160 and the organic semiconductor layer 150 are etched by using the photoresist 500 as an etch mask to form the protective members 164 and the organic semiconductor islands 154.

Referring to FIGS. 10 and 11, a passivation layer 180 is deposited and patterned along with the gate insulating layer 140 to form contact holes 181, 182 and 185 exposing the end portions 129 of the gate lines 121, the end portions 179 of the data lines 171, and portions of the drain electrodes 175, respectively.

Next, pixel electrodes 190 and contact assistants 81 and 82 are formed on the passivation layer 180, as shown in FIGS. 1 and 2.

Since the organic semiconductor layer 150 is patterned using a normal positive photoresist, the manufacturing method of the TFT array panel is simplified. Furthermore, the insulating layer 160 prevents the organic semiconductor layer 150 from being deteriorated to improve reliability of the TFTs.

The present invention can be employed to any display devices including LCD and OLED.

Although exemplary embodiments of the present invention have been described in detail hereinabove, it should be clearly understood that many variations and/or modifications of the basic inventive concepts taught herein which may appear to those skilled in the present art will still fall within the spirit and scope of the present invention, as defined by the appended claims.

1. A method of manufacturing a thin film transistor array panel, the method comprising:
forming a gate line on a substrate;
forming a gate insulating layer on the gate line;
forming a data line and a drain electrode on the gate insulating layer;
depositing an organic semiconductor layer on the data line, the drain electrode and exposed portions of the gate insulating layer;
depositing a protection layer on the organic semiconductor layer;
forming a photoresist on the protection layer, the photoresist having a positive photosensitivity;
etching the protection layer and the organic semiconductor layer using the photoresist as an etch mask;
forming a passivation layer on the protection layer, the data line, and the drain electrode, the passivation layer having a contact hole exposing a portion of the drain electrode; and
forming a pixel electrode on the passivation layer, the pixel electrode electrically connected to the drain electrode via the contact hole.

2. The method of claim 1, wherein the protection layer comprises aqueous-based organic material.

3. The method of claim 2, wherein the protection layer is insensitive to light.

4. The method of claim 1, wherein the protection layer is insensitive to light.

5. The method of claim 1, wherein the protection layer comprises polyvinyl alcohol (PVA).

6. The method of claim 1, wherein the organic semiconductor layer is soluble in an organic solvent.

7. The method of claim 1, wherein the organic semiconductor layer comprises at least one of:
tetracene, pentacene, and derivatives thereof with substituent;
oligothiophene including four to eight thiophenes connected at the positions 2, 5 of thiophene rings;
perylenetetracarboxylic dianhydride (PTCDA), naphthalenetetracarboxylic dianhydride (NTCDA), and imide derivatives thereof;
metallized phthalocyanine and halogenated derivatives thereof;
co-oligomer and co-polymer of thienylene and vinylene;
regioregular polythiophene;
perylene, coronene, and derivatives thereof with substituent; and
aromatic and heteroaromatic ring of the above-described materials with at least one hydrocarbon chain having one to thirty carbon atoms.

8. The method of claim 1, wherein the gate insulating layer comprises at least one of silicon dioxide, silicon nitride, maleimide-styrene, polyvinylphenol (PVP), and modified cyanoethylpullulan (m-CEP).

9. The method of claim 8, wherein the gate insulating layer is surface treated with octadecyl-trichloro-silane.

10. The method of claim 1, wherein the forming a photoresist on the protection layer further comprises disposing the photoresist at a portion of the protection layer corresponding to a portion of the drain electrode, a portion of a gate electrode of the gate line, and a portion of a source electrode of the data line.

11. A thin film transistor array panel comprising:
a gate line formed on a substrate;
a gate insulating layer formed on the gate line;
a data line and a drain electrode formed on the gate insulating layer;
an organic semiconductor formed on a portion of the data line and a portion of the drain electrode;
a protection member formed on the organic semiconductor and having substantially a same planar shape as the organic semiconductor;
a passivation layer formed on the protective member, a portion of the data line, and a portion of the drain electrode, the passivation layer having a contact hole exposing a portion of the drain electrode; and
a pixel electrode formed on the passivation layer, the pixel electrode electrically connected to the drain electrode via the contact hole.

12. The thin film transistor array panel of claim 11, wherein the protective member comprises aqueous-based organic material.

13. The thin film transistor array panel of claim 12, wherein the protective member is insensitive to light.

14. The thin film transistor array panel of claim 11, wherein the protective member is insensitive to light.

15. The thin film transistor array panel of claim 11, wherein the protective member comprises polyvinyl alcohol (PVA).

16. The thin film transistor array panel of claim 11, wherein the organic semiconductor is soluble in an organic solvent.

17. The thin film transistor array panel of claim 11, wherein the organic semiconductor comprises at least one of:
tetracene, pentacene, and derivatives thereof with substituent;
oligothiophene including four to eight thiophenes connected at the positions 2, 5 of thiophene rings;
perylenetetracarboxylic dianhydride (PTCDA), naphthalenetetracarboxylic dianhydride (NTCDA), and imide derivatives thereof;
metallized phthalocyanine and halogenated derivatives thereof;
co-oligomer and co-polymer of thienylene and vinylene;
regioregular polythiophene;
perylene, coronene, and derivatives thereof with substituent; and
aromatic and heteroaromatic ring of the above-described materials with at least one hydrocarbon chain having one to thirty carbon atoms.

18. The thin film transistor array panel of claim 11, wherein the gate insulating layer comprises at least one of silicon dioxide and silicon nitride having a surface treated by octadecyl-trichloro-silane, maleimide-styrene, polyvinylphenol (PVP), and modified cyanoethylpullulan (m-CEP).

19. The thin film transistor array panel of claim 18, wherein the gate insulating layer is surface treated with octadecyl-trichloro-silane.

20. The thin film transistor array panel of claim 11, wherein the gate line comprises a gate electrode extended from the gate line and substantially fully covered by the organic semiconductor.
